(19) United States
(12) Patent Application Publication
(10) Pub. No.: US 2025/0154682 A1
(43) Pub. Date: May 15, 2025

(54) HETEROEPITAXIAL WAFER FOR THE DEPOSITION OF GALLIUM NITRIDE

(71) Applicant: SILTRONIC AG, Munich (DE)

(72) Inventors: Brian MURPHY, Pfarrkirchen (DE); Sarad Bahadur THAPA, Burghausen (DE)

(21) Appl. No.: 18/838,284

(22) PCT Filed: Feb. 8, 2023
(86) PCT No.: PCT/EP2023/053061

§ 371 Date: Aug. 14, 2024

(30) Foreign Application Priority Data
Feb. 16, 2022 (EP) 22156958.5

(51) Int. Cl. C30B 25/18; C30B 29/06; C30B 29/36; C30B 29/40

(52) U.S. Cl. CPC C30B 25/183; C30B 29/06; C30B 29/36; C30B 29/403

(57) ABSTRACT

A heteroepitaxial wafer includes, in the following order: (1) a substrate made of silicon having a thickness, a diameter, and a resistivity, and including a buried gettering layer for hydrogen; (2) a 3C-SiC layer, and (3) an aluminum-nitride nucleation layer, which includes, in the given order: a first nitrogen enriched aluminum-nitride region, an aluminum-nitride region, and a second nitrogen enriched aluminum-nitride region.

This application is a U.S. National Phase application under 35 U.S.C. § 371 of International Application No. PCT/EP2023/053061, filed on Feb. 8, 2023, and claims benefit to European Patent Application No. 22156958.5, filed on Feb. 16, 2022. The International Application was published in English on Aug. 24, 2023 as WO 2023/156265 A1 under PCT Article 21 (2).

### FIELD

The present disclosure relates to a heteroepitaxial wafer that is optimized for depositing gallium nitride on it.

### BACKGROUND

Gallium nitride (GaN) offers some fundamental advantages over silicon. In particular, the higher critical electrical breakdown field makes it very attractive for power semiconductor devices with outstanding specific dynamic on-state resistance and smaller capacitances compared to silicon metal-oxide semiconductor field effect transistors (MOSFETs). So, GaN high electron mobility transistors (HEMTs) are great for high speed switching. This is not only because of the resulting power savings and total system cost reduction, it also allows a higher operating frequency, improves the power density as well as the overall system efficiency.

During growth of GaN p-n junction diodes using Metal-Organic Chemical Vapor Deposition (MOCVD), it is very difficult to grow a p-type material with good structural, optical and at the same time electrical integrity. The p-type region of a GaN junction diode is commonly grown in a MOCVD reactor by adding magnesium (Mg) to achieve the desired conductivity.

However, a common problem is the electrical passivation of acceptors like Mg, zinc (Zn), carbon (C), and others by hydrogen atoms. It is believed that hydrogen atoms diffuse into the GaN material, where they neutralize the Mg acceptors and the holes produced by the Mg.

The passivation process leaves the Mg acceptors inactive, resulting in the material becoming insulating or weakly p-type in its as grown state. The passivation of the p-type region results in critical performance problems for the diode. Hydrogen passivation of acceptors and donors has been reported for a wide variety of semiconductors including silicon [see S. J. Pearton et. al., Appl. Phys. A 43, 153 (1987)], gallium arsenide [N. M. Johnson et. al., Phys. Rev. B 33, 1102 (1986); W. C Dautremont-Smith, Mater. Res. Soc. Symp. Proc. 104, 313 (1988)], indium phosphide [G. R. Antell et. al., Appl. Phys. Lett., 53, 758 (1988)], and cadmium telluride [L. Svob et. al., J. Cryst. Growth 86, 815 (1988)].

Passivation has been demonstrated both intentionally and unintentionally as a result of the epitaxial growth process. The growth of GaN diodes represents an example where hydrogen passivation plays an important role. It has been shown that passivation of acceptors occurs after growth, during the reactor cooling stage. [G. R. Antell et al., Appl. Phys. Lett. 73, 2953 (1998)]. Hydrogen is common in a MOCVD reactor during growth of the GaN material and subsequent reactor cooling, generally coming from two sources. Hydrogen is commonly used during growth as a carrier gas for the growth source gases.

In addition, ammonia (NH₃) is used as a source gas for nitrogen (N) during growth of the GaN material and is also used to stabilize the GaN material during reactor cooling. Hydrogen is produced as a by-product of the ammonia decomposition during growth and cooling. During a conventional GaN growth process, there is sufficient hydrogen available in the reactor to cause passivation of the p-type region during cooling.

Passivation of a p-type region could theoretically be avoided by removing the hydrogen source from the reactor prior to cool down as disclosed in U.S. Pat. No. 5,891,790 A.

However, the GaN crystal is unstable at growth temperatures and the p-type GaN region is susceptible to decomposition, which results in surface damage. The conventional method for avoiding this decomposition is to maintain the flow of NH₃ during reactor cooling.

However, the presence of NH₃ during reactor cooling produces hydrogen and leads to passivation. As such, it was thought that the removal of all hydrogen sources was not practical and that passivation during reactor cooling could not be avoided.

U.S. Pat. No. 6,498,111 B1 discloses methods of fabricating passivation-barrier layers to prevent or reduce doping species passivation during the semiconductor growth process, thus eliminating or at least reducing the effects described above.

It is advantageous to heteroepitaxially grow GaN layers onto a silicon substrate, both from a perspective substrate cost and for the potential to more closely integrate GaN-based devices with silicon-based devices.

Such GaN-on-silicon (GOS) growths are difficult, to produce because of both lattice mismatch and mismatch of the linear thermal expansion coefficient between the nitride material and silicon substrate.

During a high temperature process, such as epitaxial growth, thermal expansion mismatch can cause substrate bowing and warping. Bow is a measure of vertical displacement of the substrate surface and becomes more significant as the substrate diameter increases unless the silicon substrate thickness is increased significantly to provide the greater rigidity needed to resist larger thermal mismatch stress.

Silicon substrate diameters and thicknesses are standardized, however, with little concern for GOS applications.

As a result, high temperature GaN growth that induces a bow of around 300 μm in substrate having a diameter of 200 mm and a thickness of 725 μm may induce a bow of over 650 μm for a substrate having a diameter of 300 mm and a thickness of 775 μm which is not acceptable for modern device manufacturing processes.

It is also known that hydrogen has a rather high diffusion coefficient in silicon at high temperatures. Therefore, the quality of GaN layers deposited on a silicon substrate would be reduced by hydrogen, which can diffuse into the GaN layer via the substrate.

### SUMMARY

In an embodiment, the present disclosure provides a heteroepitaxial wafer that includes, in the following order: (1) a substrate made of silicon having a thickness, a diameter, and a resistivity, and including a buried gettering layer for hydrogen; (2) a 3C—SiC layer; and (3) an aluminum-nitride nucleation layer, which includes, in the given order: a first nitrogen enriched aluminum-nitride region, an aluminum-nitride region, and a second nitrogen enriched aluminum-nitride region.

### DETAILED DESCRIPTION

Aspects of the present disclosure provide a substrate made of silicon that can be coated with doped GaN without causing described passivation effects of the dopant caused by hydrogen.

Although having some technical measures in place. the inventors realized that diffusion of hydrogen in GaN is still a problem on Si wafers. This diffusion results in quality flaws especially concerning the dopant of the GaN. The inventors realized that the diffusion of hydrogen through the backside of the wafer (through silicon) is responsible for that.

In a preferred implementation of the Si wafer of the present disclosure, there is provided a combination of layers that can prevent the diffusion through gettering, barriers and passivation/neutralization of the malign effects of hydrogen on dopants.

The granted patent document U.S. Pat. No. 6,498,111 B1 teaches methods of fabricating passivation-barrier layers to prevent or reduce doping species passivation during the semiconductor growth process, thus eliminating the need for in-situ or ex-situ annealing steps. However, the inventors realized that the methods presented in the prior art are not sufficient to entirely solve the problem.

Preferably, a substrate that can be used of a for heteroepitaxial wafer comprises a silicon substrate which is oriented in <1-1-1> direction.

Preferably, the thickness of the substrate is more than 700 μm and less than 1100 μm.

Preferably the diameter of the substrate is more than 125 mm and less than 310 mm.

The resistivity of the silicon substrate layer depends on the power device application. In many power device applications conducting substrates are preferred. If electrical conducting substrates are required, the resistivity is preferably less than 10 mOhmcm. If RF HEMT devices semi-insulating or insulating substrates are required, resistivity is preferably higher than 1000 Ohmcm with a low Oᵢ concentration of preferably less than 2×10¹⁷ At/cm³. So, the resistivity of the silicon substrate preferably is less than 10 mOhmcm or more than 1000 Ohmcm.

The inventors further realized that it is most preferred to use a substrate having an interstitial oxygen content of less than 2×10¹⁷ At/cm³ (ASTM-Norm F121-83) and at the same time the resistivity of the silicon substrate is more than 1000 Ohmcm.

Preferably, the silicon substrate comprises an intermediate or buried gettering layer that is able to getter the diffusing species of hydrogen.

The gettering layer preferably comprises a stress field or implanted helium or oxygen layer to disturb the crystal and thus gettering the hydrogen species. More preferably the gettering layer comprises a “stable getterer”. A “stable getterer” is understood as crystal defects that act as gettering centers for metals that maintain the gettering properties even after high temperature processing steps lasting up to 30 minutes at a temperature up to 1200° C.

As an example of the above mentioned stable getterer voids can be generated by helium implantation in the crystal, and those voids can be stabilized by co-implantation of oxygen. It is understood that the implanted oxygen atoms form silicon oxide on the surface of the inner walls of the generated voids, and thus, stabilizes those voids.

To determine the efficiency of the gettering, a test can be carried out in the course of which the wafer to be tested is intentionally contaminated with metal ions on the back side (“Graff test”). The impurities are then driven into the crystal lattice by heating the semiconductor wafer. If no effective getter centers are present, they can reach the front side of the semiconductor wafer, where they can be detected by etching and by means of scattered light measurement (haze measurement). This test can be performed, for example, with impurities such as copper (Cu), iron (Fe), nickel (Ni) or palladium (Pd). This test is performed using metals as contaminants; however, the inventors came the conclusion that this test is valid for hydrogen, too.

The inventors understood that the end of range damage during the implantation process can create some getter centers for the hydrogen species. This measure is effective even at elevated temperatures which are common during the device manufacturing process. More preferably, the gettering layer comprises voids.

Preferably, the silicon substrate is covered by a 3C—SiC epitaxial layer. Even more preferably, the epitaxial layer is covered by a layer of Aluminum-Nitride.

The Aluminum-Nitride layer which is made by MOCVD preferably comprises in the given order a first nitrogen enriched Aluminum-Nitride region, an Aluminum-Nitride region and a second nitrogen enriched Aluminum-Nitride region.

So, a region of the nitrogen enriched Aluminum-Nitride is preferably in contact with the 3C—SiC layer. This region is thought to act as a passivation layer.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A heteroepitaxial wafer, the heteroepitaxial wafer comprising, in the following order:
(1) a substrate made of silicon having a thickness, a diameter, and a resistivity, and comprising a buried gettering layer for hydrogen;
(2) a 3C—SiC layer; and
(3) an aluminum-nitride nucleation layer, comprising in the given order; a first nitrogen enriched aluminum-nitride region, an aluminum-nitride region, and a second nitrogen enriched aluminum-nitride region.

2. The heteroepitaxial wafer according to claim 1, wherein:
the gettering layer comprises voids.

3. The heteroepitaxial wafer according to claim 1, wherein:
the gettering layer comprises end of range damage.

4. The heteroepitaxial wafer according to claim 1, wherein:
the crystal orientation of the substrate is <1-1-1>.

5. The heteroepitaxial wafer according to claim 1, wherein:
the diameter is more than 125 mm and less than 310 mm.

6. The heteroepitaxial wafer according to claim 1, wherein:
the thickness is more than 700 μm and less than 1100 μm.

7. The heteroepitaxial wafer according to claim 1, wherein:
the resistivity of the silicon substrate is less than 10 mOhmcm.

8. The heteroepitaxial wafer according to claim 1, wherein:
the resistivity of the silicon substrate is more than 1000 Ohmcm.

9. The heteroepitaxial wafer according to claim 8, wherein:
the oxygen content of the silicon substrate is less than 2×10¹⁷ At/cm³ (ASTM-Norm F121-83).
